(19) United States
(12) Patent Application Publication
(10) Pub. No.: US 2006/0220090 A1
(43) Pub. Date: Oct. 5, 2006

(54) Semiconductor device with a high-k gate dielectric and a metal gate electrode

(75) Inventors: Matthew V. Metz, Hillsboro, OR (US); Suman Datta, Beaverton, OR (US); Mark L. Doczy, Beaverton, OR (US); Jack Kavalieros, Portland, OR (US); Justin K. Brask, Portland, OR (US); Brian S. Doyle, Portland, OR (US); Marko Radosavljevic, Beaverton, OR (US); Robert S. Chau, Beaverton, OR (US)

Correspondence Address: INTEL CORPORATION, P.O. BOX 5326, SANTA CLARA, CA, 95056-5326, US

(73) Assignee: Intel Corporation

(21) Appl. No.: 11/089,247

(22) Filed: Mar. 23, 2005

(51) Int. Cl. H01L 29/94

(52) U.S. Cl. 257/310

(57) ABSTRACT

A semiconductor device is described. That semiconductor device comprises a high-k gate dielectric layer that is formed over a channel that is positioned within a substrate, and a metal gate electrode that is formed on the high-k gate dielectric layer. The high-k gate dielectric layer has off-state leakage characteristics that are superior to those of a silicon dioxide based gate dielectric, and on-state mobility characteristics that are superior to those of a high-k gate dielectric that comprises an isotropic material.

### FIELD OF THE INVENTION

The present invention relates to semiconductor devices, in particular, those with high-k gate dielectrics and metal gate electrodes.

### BACKGROUND OF THE INVENTION

MOS field-effect transistors with very thin silicon dioxide based gate dielectrics may experience unacceptable off-state leakage. Forming the gate dielectric from certain high-k dielectric materials can reduce gate leakage. Replacing low-k silicon dioxide with a high-k material may, however, degrade mobility.

Accordingly, there is a need for a semiconductor device with a high-k gate dielectric that has both acceptable off-state leakage and on-state mobility characteristics. The present invention discloses such a semiconductor device.

### BRIEF DESCRIPTION OF THE DRAWINGS

FIG. 1 represents a cross-section of the semiconductor device of the present invention.

FIGS. 2a and 2b graphically illustrate the relative dielectric constants for isotropic and anisotropic materials in vertical and horizontal directions.

FIGS. 3a-3c graphically illustrate how the crystal lattice of piezoelectric materials may change when subject to an electric field.

Features shown in these figures are not intended to be drawn to scale.

### DETAILED DESCRIPTION OF THE PRESENT INVENTION

A semiconductor device is described. That semiconductor device comprises a high-k gate dielectric layer that is formed over a channel that is positioned within a substrate, and a metal gate electrode that is formed on the high-k gate dielectric layer. The high-k gate dielectric layer has off-state leakage characteristics that are superior to those of a silicon dioxide based gate dielectric, and on-state mobility characteristics that are superior to those of a high-k gate dielectric that comprises an isotropic material.

In the following description, a number of details are set forth to provide a thorough understanding of the present invention. It will be apparent to those skilled in the art, however, that the invention may be practiced in many ways other than those expressly described here. The invention is thus not limited by the specific details disclosed below.

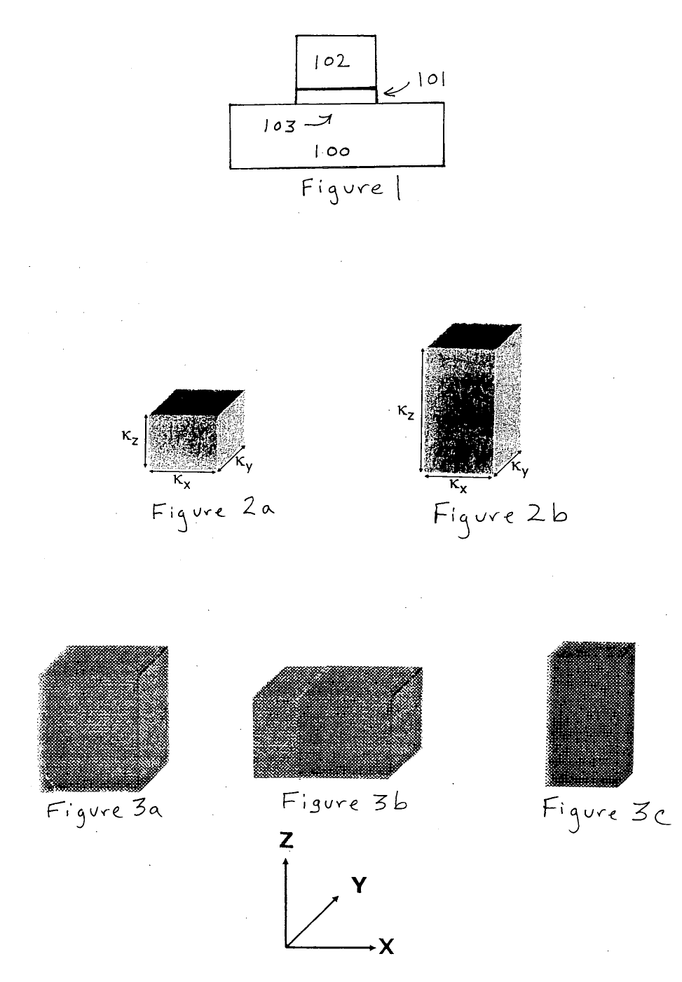

FIGS. 1 represents a cross-section of the semiconductor device of the present invention. In that semiconductor device, high-k gate dielectric layer 101 is formed on substrate 100, and metal gate electrode 102 is formed on high-k gate dielectric layer 101. Substrate 100 may comprise any material that may serve as a foundation upon which a semiconductor device may be built. High-k gate dielectric layer 101 is formed over channel 103, which is positioned within substrate 100. High-k gate dielectric layer 101 has off-state leakage characteristics that are superior to those of a silicon dioxide based gate dielectric, and on-state mobility characteristics that are superior to those of a high-k gate dielectric that comprises an isotropic material.

In one embodiment, high-k gate dielectric layer 101 comprises an anisotropic material with a dielectric constant parallel to the vertical electric field that is greater than the dielectric constant in the plane perpendicular to the vertical electric field. Such an anisotropic material may comprise a titanate, such as strontium titanium oxide, barium titanium oxide, or barium strontium titanium oxide. Although a few examples of materials are mentioned here, which may be used to form a high-k gate dielectric layer that shows anisotropic dielectric properties, other materials may be used instead—as will be apparent to those skilled in the art.

FIGS. 2a and 2b graphically illustrate the relative dielectric constants for isotropic and anisotropic materials in vertical and horizontal directions. FIG. 2a provides a dielectric constant profile for a high-k gate dielectric layer that comprises an isotropic material. The dielectric constant properties of such a material may be like those of an amorphous or polycrystalline film. In such a film, the dielectric constant in the vertical direction (k_{z}) may be about equal to the dielectric constant in the horizontal plane (kₓ and k_{y}), as FIG. 2a indicates.

The performance characteristics of a transistor that includes a high-k gate dielectric formed from such a film may be suboptimal. Consider an NMOS transistor with an isotropic high-k film. After the transistor is turned on, electrons moving from the transistor's source to the transistor's drain may interact with soft phonons from the high-k film, which may reduce mobility. That interaction may intensify with increasing k value for the dielectric. For that reason, when forming a high-k gate dielectric from a material with isotropic dielectric properties, any off-state leakage benefit that such a dielectric provides may be offset by lowered mobility characteristics.

FIG. 2b provides a dielectric constant profile for a high-k gate dielectric layer that is formed from a vertically aligned anisotropic material. In such a film, the dielectric constant in the vertical direction (k_{z}) is greater than the dielectric constant in the horizontal plane (kₓ and k_{y}), as that figure shows. Like a transistor with an isotropic high-k gate dielectric, a transistor with an anisotropic high-k gate dielectric may provide favorable off-state leakage characteristics. Unlike a device with an isotropic film, however, a transistor with a vertically aligned anisotropic high-k gate dielectric may also provide favorable on-state mobility properties. Superior mobility results because of the dielectric's relatively low dielectric constant in the plane perpendicular to the vertical electric field, when compared to the relatively high dielectric constant in the direction parallel to the vertical electric field.

When used to form an NMOS transistor, the dielectric constant of the anisotropic high-k gate dielectric layer as measured parallel to the vertical electric field is greater than the dielectric constant in the plane parallel to electron flow. When used to form a PMOS transistor, the dielectric constant of the anisotropic high-k gate dielectric layer as measured parallel to the vertical electric field is greater than the dielectric constant in the plane parallel to hole flow.

In this embodiment, high-k gate dielectric layer 101 must be formed on a surface, and via a process, which ensures: (1) that the film will have an anisotropic dielectric constant, and (2) that the film will be aligned such that the dielectric constant in the direction of the vertical electric field is greater than the dielectric constant in the plane perpendicular to the vertical electric field. Molecular beam epitaxy (“MBE”) or chemical vapor deposition epitaxy (“CVDE”) may be used to generate an anisotropic high-k film with the proper orientation. MBE may be preferred for a number of reasons. MBE may enable high quality films with abrupt junctions, controlled thickness and desired composition. MBE's relatively slow growth rates (measured in angstroms per second for many materials) may enable nearly atomically abrupt transitions from one material to another—especially when the MBE equipment allows beams to be shuttered in a fraction of a second.

Another advantage to MBE is its proven ability to form thin titanate films on silicon substrates. See, e.g., F. Amy et al., “Surface and interface chemical composition of thin epitaxial SrTiO₃ and BaTiO₃ films: Photoemission investigation,” J. Appl. Phys. 96, 1601 (2004); F. Amy et al., “Band offsets at heterojunctions between SrTiO₃ and BaTiO₃ and Si(100),” J. Appl. Phys. 96, 1635 (2004); and S. A. Chambers et al., “Band discontinuities at epitaxial SrTiO₃/Si(001) heterojunctions,” Appl. Phys. Left. 77, 1662 (2000).

Those skilled in the art will recognize that the process for forming high-k gate dielectric layer 101 on substrate 100 must enable the resulting film to have an anisotropic dielectric constant, and to be formed on substrate 100 such that the high dielectric component of its structure is aligned with the vertical electric field. To generate a high-k gate dielectric layer that is both anisotropic and properly aligned, it may be necessary to form that layer on a properly constituted substrate. Similarly, to form a properly aligned anisotropic layer, it may be necessary to tailor any surface treatment that precedes dielectric growth, as well as the process for depositing the film, such that they are conducive to growth of a high-k gate dielectric layer with the desired properties.

To create the semiconductor device of this embodiment of the present invention, those skilled in the art will recognize that materials, equipment and process steps must be selected to form a properly aligned anisotropic high-k gate dielectric layer. The MBE, CVDE, or other process used to deposit such a layer on substrate 100 should progress until a layer with the desired thickness is formed. In most applications, the resulting vertically aligned anisotropic high-k gate dielectric layer should be between about 10 angstroms and about 50 angstroms thick.

As illustrated above, forming an anisotropic high-k gate dielectric layer on substrate 100, and aligning that film's highest k orientation with the vertical electric field, may enable a device with high capacitance in the vertical direction without significantly degrading mobility. In a second embodiment of the present invention, high-k gate dielectric layer 101 instead comprises a piezoelectric material that may be used in a reverse piezoelectric mode (electrostriction). When an electric field is applied to such a material, the crystal lattice may be reconfigured. One may exploit this effect to create a transistor, which includes a piezoelectric gate dielectric, that has both acceptable off-state leakage and on-state mobility properties.

Piezoelectric materials that may be used in this embodiment of the present invention include lead zirconate titanate (“PZT”) and other titanate films. Such piezoelectric materials may be used to form either NMOS or PMOS transistors. When forming the gate dielectric for an NMOS transistor, an appropriate piezoelectric material is deposited over the transistor channel such that the axis parallel to electron conduction will expand when an electric field is applied. When the transistor is turned on, the resulting electric field causes the piezoelectric material to expand along the direction of current flow. That material's expansion along the channel conduction plane may apply a tensile stress on the channel. By causing uni-axial or bi-axial tensile strain in the channel, electron mobility should increase and the NMOS transistor's performance should improve.

When forming the gate dielectric for a PMOS transistor, an appropriate piezoelectric material is deposited over the transistor channel such that the axis parallel to hole flow will contract when an electric field is applied. When the transistor is turned on, the resulting electric field causes the piezoelectric material to contract along the direction of hole flow. That material's contraction may compress the channel. As a result, mobility should increase and the PMOS transistor's performance should improve.

FIGS. 3a-3c graphically illustrate how the crystal lattice of piezoelectric materials may change when subject to an electric field. FIG. 3a represents the configuration of the crystal lattice of a piezoelectric material, when a transistor is in an off-state. FIG. 3b represents the configuration of the crystal lattice of a piezoelectric material, when an NMOS transistor is in an on-state. Here, the electric field causes the piezoelectric material to expand in the x and y directions, while contracting in the z direction. FIG. 3c represents the configuration of the crystal lattice of a piezoelectric material, when a PMOS transistor is in an on-state. In this case, the electric field causes the piezoelectric material to contract in the x and y directions, while expanding in the z direction.

As FIGS. 3a-3c illustrate, when a device is in the off-state, the piezoelectric gate dielectric does not apply strain to the channel. Strain results only when the device is turned on. Because strain is absent when the transistor is turned off, the resulting device should demonstrate favorable off-state leakage characteristics. Because strain is applied when the transistor is turned on, desirable on-state mobility properties should also result.

Unlike this device, transistors formed using conventional strained silicon techniques may not offer both optimal off-state leakage and on-state mobility. It is believed that those conventional techniques enhance mobility by reducing the material's band gap. A lowered band gap, however, may cause higher off-state leakage. The piezoelectric gate dielectric described above will induce strain (and reduce the band gap) only when the device is switched on. The off-state leakage of a device with such a gate dielectric should, therefore, be measurably less than the off-state leakage of a transistor that is made using conventional strained silicon processes. Although FIGS. 3a-3c illustrate how an electric field may reconfigure piezoelectric gate dielectrics, these figures are not intended to reflect the magnitude of that transformation.

In this second embodiment, high-k gate dielectric layer 101 must be formed on a surface, and via a process, which ensures: (1) that the film behaves as a piezoelectric material that may be used in a reverse piezoelectric mode, and (2) that the film will be aligned such that the crystal lattice will expand along the direction of current flow, when included in an NMOS transistor, and will contract along the direction of hole flow, when included in a PMOS transistor. MBE or CVDE may be used to generate a piezoelectric gate dielectric with the proper orientation.

Those skilled in the art will recognize that the process for forming a piezoelectric gate dielectric layer on substrate 100 must enable the resulting film to have the desired piezoelectric properties, and to be properly oriented. To generate a high-k gate dielectric layer with both the necessary piezoelectric properties and the proper alignment, it may be necessary to form that layer on a properly constituted substrate. Similarly, to form a properly aligned piezoelectric gate dielectric, it may be necessary to tailor any surface treatment that precedes dielectric growth, as well as the process for depositing the film, such that they are conducive to growth of a high-k gate dielectric layer with the desired properties.

When making a CMOS device that includes a piezoelectric gate dielectric, different materials and process steps may be used to form the gate dielectrics for the NMOS and PMOS devices. Alternatively, it may be possible to use the same piezoelectric material for both NMOS and PMOS devices. If the substrate upon which the NMOS device will be formed differs from the substrate upon which the PMOS device will be formed, the piezoelectric material may assume one configuration when deposited over the NMOS substrate, but another configuration when deposited over the PMOS substrate. Differences in substrate composition may enable the same piezoelectric material that induces tensile strain in the channel of an NMOS transistor to compress the channel of a PMOS transistor by simply causing the piezoelectric material to have different crystalline orientations, when deposited over the PMOS and NMOS channels. This outcome may be possible, for example, if substrate differences cause the crystal lattice to assume an orientation over the PMOS channel that is rotated 90° from the orientation over the NMOS channel.

To create the semiconductor device of this second embodiment of the present invention, those skilled in the art will recognize that materials, equipment and process steps must be selected to form a properly aligned piezoelectric gate dielectric layer. Like the embodiment described above, the piezoelectric dielectric layer of this second embodiment has off-state leakage characteristics that are superior to those of a silicon dioxide based gate dielectric, and on-state mobility characteristics that are superior to those of a high-k gate dielectric that comprises an isotropic material.

Irrespective of whether high-k gate dielectric layer 101 comprises a vertically aligned anisotropic material or a piezoelectric material, metal gate electrode 102 may be formed on high-k gate dielectric layer 101. Metal gate electrode 102 may be formed using conventional metal deposition processes, and may comprise any conductive material from which metal gate electrodes may be derived. Materials that may be used to form n-type metal gate electrodes include: hafnium, zirconium, titanium, tantalum, aluminum, their alloys (e.g., metal carbides that include these elements, i.e., hafnium carbide, zirconium carbide, titanium carbide, tantalum carbide, and aluminum carbide), and aluminides (e.g., an aluminide that comprises hafnium, zirconium, titanium, tantalum, or tungsten). Materials for forming p-type metal gate electrodes include: ruthenium, palladium, platinum, cobalt, nickel, and conductive metal oxides, e.g., ruthenium oxide.

Metal NMOS gate electrodes preferably have a workfunction that is between about 3.9 eV and about 4.2 eV. Metal PMOS gate electrodes preferably have a workfunction that is between about 4.9 eV and about 5.2 eV. A metal gate electrode that is formed on high-k gate dielectric layer 101 may consist essentially of a homogeneous metal layer. Alternatively, relatively thin n-type or p-type metal layers (like those listed above) may generate the lower part of the metal gate electrode, with the remainder of the metal gate electrode comprising another metal or metals, e.g., a metal that may be easily polished like tungsten, aluminum, titanium, or titanium nitride. Although a few examples of materials for forming a metal gate electrode are identified here, such a component may be made from many other materials, as will be apparent to those skilled in the art.

The semiconductor device of the present invention has acceptable off-state leakage and on-state mobility characteristics. As described above, such properties may result from using a high-k gate dielectric layer with a vertically aligned anisotropic dielectric constant, or from using a high-k gate dielectric layer that is formed from a piezoelectric material. Although the foregoing description has specified some embodiments of the semiconductor device of the present invention, those skilled in the art will appreciate that many modifications and substitutions may be made. Accordingly, all such modifications, substitutions and additions fall within the spirit and scope of the invention as defined by the appended claims.

What is claimed is:

1. A semiconductor device comprising:
a high-k gate dielectric layer that is formed over a channel that is positioned within a substrate, the high-k gate dielectric layer having:
off-state leakage characteristics that are superior to those of a silicon dioxide based gate dielectric, and
on-state mobility characteristics that are superior to those of a high-k gate dielectric that comprises an isotropic material; and
a metal gate electrode that is formed on the high-k gate dielectric layer.

2. The semiconductor device of claim 1 wherein the high-k gate dielectric layer is between about 10 angstroms and about 50 angstroms thick, and is formed using molecular beam epitaxy.

3. The semiconductor device of claim 1 wherein the high-k gate dielectric layer comprises an anisotropic material with a dielectric constant parallel to the vertical electric field that is greater than the dielectric constant in the plane perpendicular to the vertical electric field.

4. The semiconductor device of claim 3 wherein the anisotropic material is selected from the group consisting of strontium titanium oxide, barium titanium oxide, and barium strontium titanium oxide.

5. The semiconductor device of claim 3 wherein the metal gate electrode is an NMOS metal gate electrode that comprises a material that is selected from the group consisting of hafnium, zirconium, titanium, tantalum, aluminum, a metal carbide, and an aluminide, and the dielectric constant of the anisotropic material parallel to the vertical electric field is greater than the dielectric constant in the plane parallel to electron flow.

6. The semiconductor device of claim 3 wherein the metal gate electrode is a PMOS metal gate electrode that comprises a material that is selected from the group consisting of ruthenium, palladium, platinum, cobalt, nickel, and a conductive metal oxide, and the dielectric constant of the anisotropic material parallel to the vertical electric field is greater than the dielectric constant in the plane parallel to hole flow.

7. The semiconductor device of claim 1 wherein the high-k gate dielectric layer comprises a piezoelectric material whose crystal lattice may be reconfigured when an electric field is applied to the piezoelectric material.

8. The semiconductor device of claim 7 wherein the metal gate electrode is an NMOS metal gate electrode, the piezoelectric material is a titanate, and the piezoelectric material induces tensile strain in the channel, when the metal gate electrode is in the on-state, but does not induce tensile strain in the channel, when the metal gate electrode is in the off-state.

9. The semiconductor device of claim 7 wherein the metal gate electrode is a PMOS metal gate electrode, the piezoelectric material is a titanate, and the piezoelectric material compresses the channel when the metal gate electrode is in the on-state, but does not compress the channel when the metal gate electrode is in the off-state.

10. A semiconductor device comprising:
a high-k gate dielectric layer that is formed from an anisotropic material, which has a dielectric constant parallel to the vertical electric field that is greater than the dielectric constant in the plane perpendicular to the vertical electric field, the high-k gate dielectric layer being formed over a channel that is positioned within a substrate; and
a metal gate electrode that is formed on the high-k gate dielectric layer.

11. The semiconductor device of claim 10 wherein the anisotropic material is selected from the group consisting of strontium titanium oxide, barium titanium oxide, and barium strontium titanium oxide.

12. The semiconductor device of claim 10 wherein the high-k gate dielectric layer is between about 10 angstroms and about 50 angstroms thick, and is formed using molecular beam epitaxy.

13. The semiconductor device of claim 10 wherein the metal gate electrode is an NMOS metal gate electrode that comprises a material that is selected from the group consisting of hafnium, zirconium, titanium, tantalum, aluminum, a metal carbide, and an aluminide, and the dielectric constant of the anisotropic material parallel to the vertical electric field is greater than the dielectric constant in the plane parallel to electron flow.

14. The semiconductor device of claim 10 wherein the metal gate electrode is a PMOS metal gate electrode that comprises a material that is selected from the group consisting of ruthenium, palladium, platinum, cobalt, nickel, and a conductive metal oxide, and the dielectric constant of the anisotropic material parallel to the vertical electric field is greater than the dielectric constant in the plane parallel to hole flow.

15. A semiconductor device comprising:
a high-k gate dielectric layer that is formed on a substrate; and
a metal gate electrode that is formed on the high-k gate dielectric layer;
wherein the high-k gate dielectric layer applies greater stress to an underlying channel when the metal gate electrode is in an on-state than when the metal gate electrode is in an off-state.

16. The semiconductor device of claim 15 wherein the high-k gate dielectric layer induces tensile strain in the underlying channel, when the metal gate electrode is in the on-state, but does not induce tensile strain in the underlying channel, when the metal gate electrode is in the off-state.

17. The semiconductor device of claim 15 wherein the high-k gate dielectric layer compresses the underlying channel, when the metal gate electrode is in the on-state, but does not compress the underlying channel, when the metal gate electrode is in the off-state.

18. The semiconductor device of claim 15 wherein the high-k gate dielectric layer is formed from a piezoelectric material whose crystal lattice may be reconfigured when an electric field is applied to the piezoelectric material.

19. The semiconductor device of claim 18 wherein the metal gate electrode is an NMOS metal gate electrode, the piezoelectric material is a titanate, and the piezoelectric material induces tensile strain in the underlying channel, when the metal gate electrode is in the on-state, but does not induce tensile strain in the underlying channel, when the metal gate electrode is in the off-state.

20. The semiconductor device of claim 18 wherein the metal gate electrode is a PMOS metal gate electrode, the piezoelectric material is a titanate, and the piezoelectric material compresses the underlying channel, when the metal gate electrode is in the on-state, but does not compress the underlying channel, when the metal gate electrode is in the off-state.
